(19) United States
(12) Patent Application Publication
(10) Pub. No.: US 2008/0220614 A1
(43) Pub. Date: Sep. 11, 2008

(54) METHOD FOR MANUFACTURING IMAGE SENSOR DEVICE

(75) Inventors: Cheng-Hsing Chuang, Taipei City (TW); Tsuan-Lun Lung, Hsinchu City (TW); Chih-Hung Cheng, Hsinchu County (TW); Wei-Chen Sun, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNITED MICROELECTRONICS CORP., Hsinchu (TW)

(21) Appl. No.: 12/119,510

(22) Filed: May 13, 2008

Related U.S. Application Data
(62) Division of application No. 11/163,936, filed on Nov. 4, 2005.

(51) Int. Cl. H01L 21/306

(52) U.S. Cl. 438/704; 257/E21.215

(57) ABSTRACT

The invention is directed to a method for manufacturing an image sensor device. The method comprises steps of forming a photodiode and a transistor on a substrate. A salicide block is formed over a photo-sensing region of the photodiode. An interconnects processes is performed several times to forming a plurality of dielectric layers over the substrate and interconnects between the dielectric layers. A photolithography and etching process is performed to remove the dielectric layers over the photo-sensing region to expose the salicide block over the photo-sensing region.

### CROSS-REFERENCE TO RELATED APPLICATION

This application is a divisional of an application Ser. No. 11/163,936, filed on Nov. 4, 2005, now pending. The entirety of the above-mentioned patent applications is hereby incorporated by reference herein and made a part of this specification.

### BACKGROUND OF THE INVENTION

1. Field of Invention

The present invention relates to an image sensor device and a method for manufacturing the same. More particularly, the present invention relates to an image sensor device having a photodiode and a method for manufacturing the same.

2. Description of Related Art

Currently, the common image sensor device is the photodiode image sensor device comprising at least one reset transistor and a photo-sensing region which is composed of a diode. Taking the diode composed of an n type doped region and a p type substrate as a photo-sensing region, photodiode image sensor device is operated by applying a voltage on the gate electrode of the reset transistor. After the reset transistor is turned on, the junction capacitor of the N/P diode is charged. When the junction capacitor is charged to a high potential level, the reset transistor is turned off so that a reverse bias generated in the N/P diode to induce a depletion region. When the light incident onto the photo-sensing region of the N/P diode, the generated electron-hole pairs are separated from each other by the electric field of the depletion region. Therefore, the electrons move toward to the n type doped region. Hence, the electric potential level of the n type doped region is decreased. Simultaneously, the holes move toward to the p type substrate. If the electrons are transferred to a bus line from the n type doped region by a transistor to read the electric charges generated by the incident light without using any amplifier, this kind of photo sensor device is so called passive pixel photodiode. If the n type doped region is connected to a source follower composed of a transfer transistor, the bus line can be rapidly charged and discharged by using the mass current provided by the source follower. Therefore, voltage of the bus line is stable and the noise is low. This kind of photo sensor device to well known active pixel photodiode.

Recently, many photodiode CMOS image sensor device becomes the substitute of the charge coupled device (CCD) in the image processing procedure. These photodiode CMOS image sensor devices possess the characteristics including high quantum efficiency, low read noise, high dynamic range and random access and compatible with the CMOS manufacturing process. Therefore, it is easy to integrate the photodiode CMOS image sensor device with other control circuit, analog-digital circuit and digital signal processing circuit. However, the light sensitivity of the photodiode CMOS image sensor device integrated with a lot of other circuits is seriously affected by the other circuits.

### SUMMARY OF THE INVENTION

Accordingly, at least one objective of the present invention is to provide a method for manufacturing an image sensor device capable increasing the light sensitivity.

At least another objective of the present invention is to provide an image sensor device capable of avoiding the mass reflection of the incident light.

The other objective of the present invention is to provide a method for forming an opening of the image sensor device mentioned above capable of preventing the photo-sensing region from being damaged by the dry etching process.

To achieve these and other advantages and in accordance with the purpose of the invention, as embodied and broadly described herein, the invention provides a method for manufacturing an image sensor device. The method comprises steps of forming a photodiode and a transistor on a substrate. A salicide block is formed over a photo-sensing region of the photodiode. An interconnects processes is performed several times to forming a plurality of dielectric layers over the substrate and interconnects between the dielectric layers. A photolithography and etching process is performed to remove the dielectric layers over the photo-sensing region to expose the salicide block over the photo-sensing region.

In the preferred embodiment of the present invention, the salicide block is used as an anti-reflection layer.

In the preferred embodiment of the present invention, after the salicide block is formed and before the interconnects processes are performed, it further comprises a step of performing a self-aligned silicide process.

In the preferred embodiment of the present invention, the method for forming the salicide block on the photo-sensing region of the photodiode comprises steps of forming an oxide layer and a dielectric layer sequentially over the substrate and removing a portion of the oxide layer and the dielectric layer which is not located over the photo-sensing region.

In the preferred embodiment of the present invention, the material of the salicide block includes silicon nitride.

The present invention also provides an image sensor device. The image sensor device comprises a substrate, a photodiode, at least one transistor, a salicide block and several dielectric layers. The photodiode is located over the substrate, wherein the photodiode has a photo-sensing region. The transistor is located on the substrate adjacent to the photodiode. The salicide block is located on the photo-sensing region of the photodiode. The dielectric layers are located over the substrate, wherein an interconnects is located between each of the dielectric layers without overlapping with the photo-sensing region and the dielectric layers have an opening exposing the salicide block over the photo-sensing region.

In the preferred embodiment of the present invention, the salicide block is used as an anti-reflection layer.

In the preferred embodiment of the present invention, it further comprises an oxide layer located between the salicide block and the photo-sensing region.

In the preferred embodiment of the present invention, the material of the salicide block includes silicon nitride.

In the preferred embodiment of the present invention, the image sensor device includes a photodiode CMOS image sensor.

In the preferred embodiment of the present invention, the image sensor device includes an active pixel photodiode.

The present invention further provides a method for forming the opening of the image sensor device mentioned above. The method comprises steps of performing a dry etching process to remove a large portion of the dielectric layers in a region used to form the opening therein and performing a wet etching process to removing a small portion of the dielectric layers in the region until the salicide block over the photo-sensing region is exposed.

In the preferred embodiment of the present invention, before the dry etching process is performed, it further comprises a step of providing a first patterned photoresist layer over the dielectric layers to expose a portion of the dielectric layers in the region.

In the preferred embodiment of the present invention, after the dry etching process is performed and before the wet etching process is performed, it further comprises steps of removing the first patterned photoresist layer. A second patterned photoresist layer is formed over the dielectric layers to expose a portion of the dielectric layers in the region. A descum process is performed.

In the preferred embodiment of the present invention, after the wet etching process is performed, it further comprises a step of removing the second patterned photoresist layer.

In the preferred embodiment of the present invention, after the dry etching process is performed and before the wet etching process is performed, it further comprises a step of removing polymer residue of the dry etching process by using RCA solution.

In the preferred embodiment of the present invention, after the wet etching process is performed, it further comprises a step of removing the first patterned photoresist layer.

In the present invention, since a portion of the dielectric layers over the photo-sensing region of the photodiode is removed, the sensitivity of the photo-sensing region of the photodiode with respect to the light is increased. Moreover, because the opening over the photo-sensing region is formed by performed a dry etching process and a wet etching process sequentially, the photo-sensing region can be prevented from being damaged by the plasma bombardment of the dry etching process.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1E are cross-sectional views showing a method for manufacturing an image sensor device according to one embodiment of the present invention.

FIG. 2 is a cross-sectional view showing an image sensor device according to another embodiment of the present invention.

FIG. 3 is a flow chart showing a method for forming an opening in the dielectric layer in the image sensor device shown in FIG. 2.

### DESCRIPTION OF THE PREFERRED EMBODIMENTS

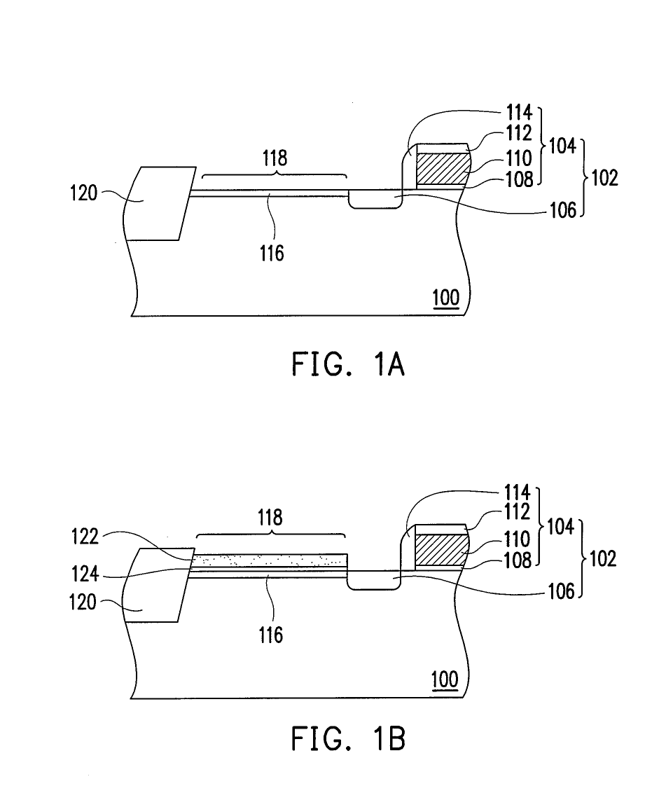

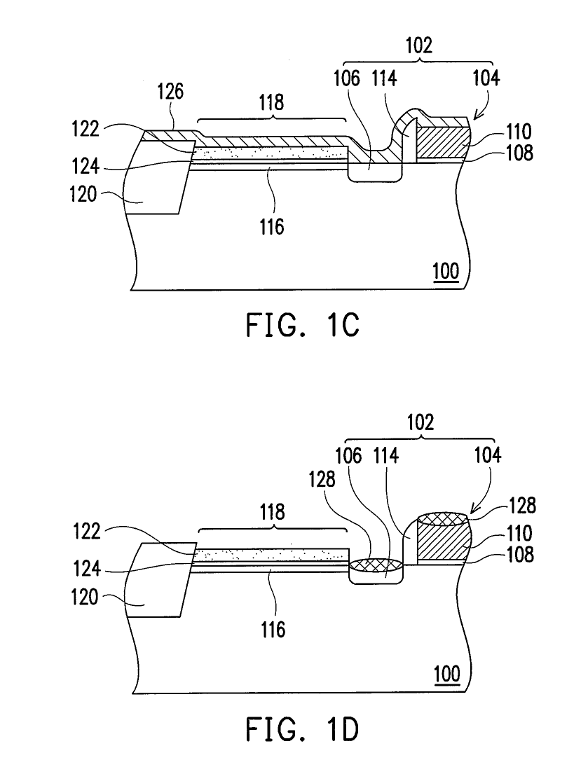

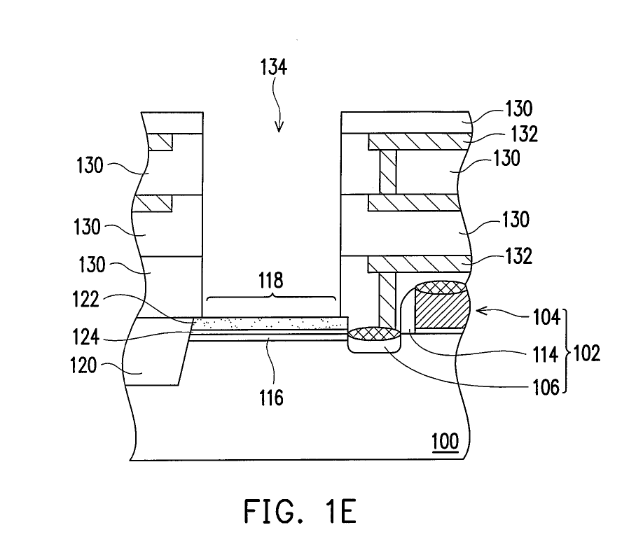

FIGS. 1A through 1E are cross-sectional views showing a method for manufacturing an image sensor device according to one embodiment of the present invention.

As shown in FIG. 1A, a substrate 100 is provided. The substrate 100 can be, for example but not limited to, a silicon substrate. The substrate 100 has a transistor 102 formed therein, wherein the transistor 102 is composed of a gate structure 104 amd a source/drain region 106. The gate structure 104 is composed of a gate oxide layer 108, a conductive layer 110, a cap layer 112 and a spacer 114. The substrate 100 further comprises a photodiode 116 having a photo-sensing region 118. Moreover, the substrate 100 comprises an isolation structure 120 formed therein. According to the type of the image sensor device, the transistor 102 can be a reset transistor, output selective, transistor or transfer transistor.

Moreover, as shown in FIG. 1B, a salicide block 122 is formed on the photo-sensing region 118. The salicide block 122 can be used as an anti-reflection layer to avoid the photo-sensing region 118 from reflecting large amount of incident light. The material of the salicide block 122 includes silicon nitride, silicon oxy-nitride or other proper material. Furthermore, before the salicide block 122 is formed, an oxide layer 124 can be formed over the photo-sensing region 118 to increase the adhesion between the salicide block 122 and the substrate 100.

Then, as shown in FIG. 1C, the cap layer 112 is removed to expose the surface of the conductive layer 110 in the gate structure 104 of the transistor 102. A self-aligned silicide process is performed by, for example, forming a metal layer 126 over the substrate 100. The metal layer 126 can be, for example but not limited to, made of titanium, tungsten, cobalt and platinum.

As shown in FIG. 1D, a silicidation process is performed on the metal layer 126 (as shown in FIG. 1C), the conductive layer 110 and a portion of the substrate 100 exposed by the salicide block 122 (such as source/drain region 106) to form a metal silicide 128. A portion of the metal layer 126 which is not reacted to be the silicide is removed. After the unreacted metal layer 126 is removed, an annealing process is performed to decrease the resistance of the metal silicide 128.

As shown in FIG. 1E, the interconnects process is performed several times to form several dielectric layers 130 over the substrate 100 and interconnects 132 are formed between each of the dielectric layers 130. The interconnects 132 include the interconnects of the image sensor device and the other semiconductor device. Then, a photolithography process is performed to remove a portion of the dielectric layers 130 over the photo-sensing region 118 to form an opening 134. The opening 134 exposes the salicide block 122.

In the embodiment of the present invention, since the dielectric layers over the photo-sensing region is removed, the sensitivity of the photo-sensing region with respect to the light is increased.

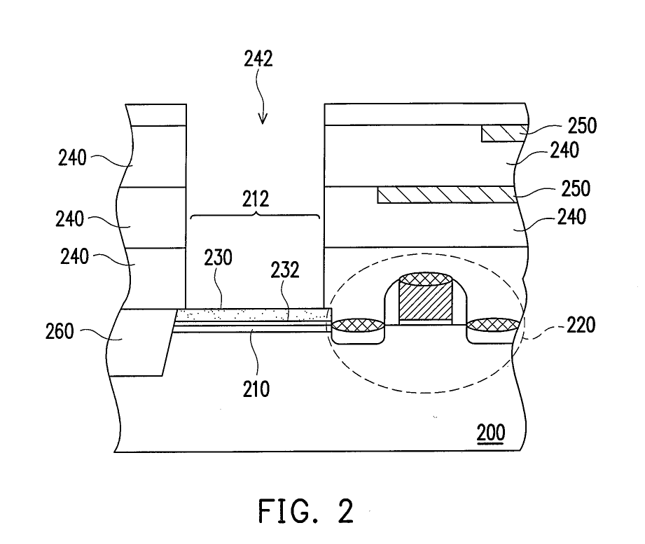

FIG. 2 is a cross-sectional view showing an image sensor device according to another embodiment of the present invention. As shown in FIG. 2, an image sensor device is composed of a substrate 200, a photodiode 210, a transistor 220, a salicide block 230, several dielectric layers 240 and interconnects 250 in the dielectric layers 240. The photodiode 210 having a photo-sensing region 212 is located in the substrate 200. The transistor 220 is located on the substrate 200 adjacent to the photodiode 210. The salicide block 230 is located over the photo-sensing region 212 of the photodiode 210, wherein the salicide block 230 can be used as an anti-reflection layer. The material of the salicide block 230 includes silicon nitride. Moreover, the dielectric layers 240 are located over the substrate 200. Furthermore, the interconnects 250 are located in the dielectric layers 240 without overlapping the photo-sensing region 212. Also, an opening 242 is located in the dielectric layers 240 to expose the salicide block 230 over the photo-sensing region 212.

As shown in FIG. 2, the image sensor device can be, for example but not limited to, a photodiode CMOS image sensor such as an active photodiode sensor. According to the type of the image sensor device, it further comprises a source follower composed of an output selective transistor and a transfer transistor. Further, there is isolation structure 260 in the substrate 200. The isolation structure 260 is used to electrically isolate the image sensor device from other semiconductor device. Additionally, if the conductive type of the substrate 200 is n type, the conductive type of the photodiode 210 is p type. On the other hand, if the conductive type of the substrate 200 is p type, the conductive type of the photodiode 210 is n type. Between the salicide block 230 and the substrate 200, it further comprises an oxide layer 232.

Because the image sensor device of this embodiment possesses an opening exposing the salicide block over the photo-sensing region, the sensitivity of the image sensor device with respect to the light is increased. Furthermore, since the salicide block used as an anti-reflection layer is located over the photodiode, the reflection of the incident light can be avoided.

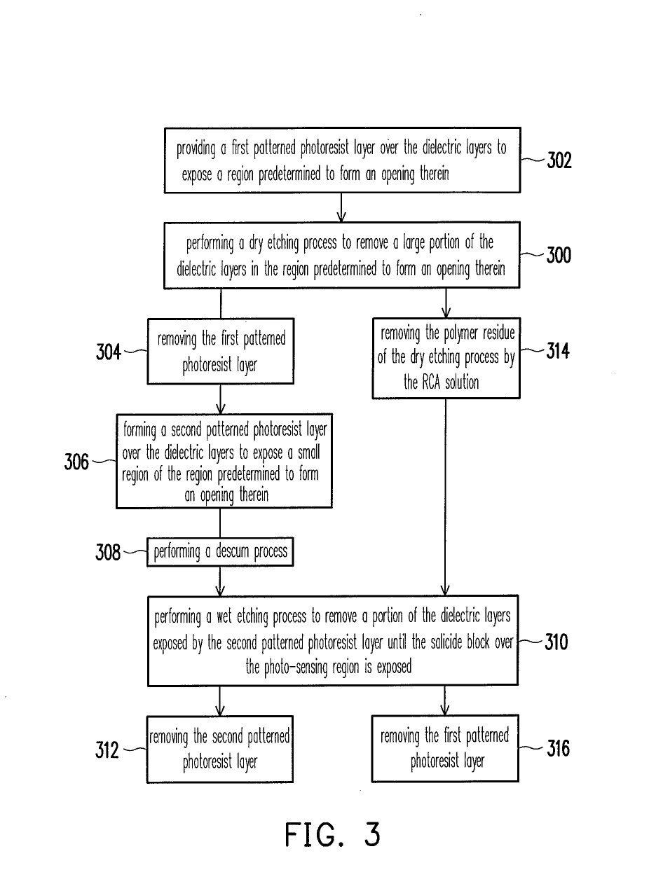

FIG. 3 is a flow chart showing a method for forming an opening in the dielectric layer in the image sensor device shown in FIG. 2. As shown in FIG. 3, in the step 300, a dry etching process is performed to remove a large portion of the dielectric layers 240 at a region predetermined to form the opening 242 therein. For example, over half thickness of the dielectric layers 240 in the region for forming the opening 242 is removed by etching. Then, in the step 310, a wet etching process is performed to remove a small portion of the dielectric layers 240 in the region for forming the opening 240 until salicide block 230 over the photo-sensing region 212 is exposed. The aforementioned steps 300 and 310 can be accomplished by performing one-time photoresist process or two-time photoresist process.

As shown in FIG. 3, when the two-time photoresist process is performed, the step 302 should be performed to provide a first patterned photoresist, layer over the dielectric layers 240 before the step 300 is performed. The first patterned photoresist layer exposes a portion of the dielectric layers 240 in the region predetermined to for the opening 242. After the step 300 is performed, the first patterned photoresist layer, is removed (step 304). In the step 306, a second patterned photoresist layer is formed over the dielectric layers 240 to expose a small portion of the dielectric layers 240 in the region for forming the opening 242. In the step 308, a descum process is performed to remove the remaining photoresist layer in the opening 242. Then, after the step 310 is performed, the second patterned photoresist layer is removed (step 312).

As shown in FIG. 3, when the one-time photoresist process is performed, the step 314 is performed after the step 300 to remove the polymer residue of the dry etching process by using RCA solution. Then, after the step 310 is performed, the first patterned photoresist layer is removed (step 316).

Since the selectivity of the wet etching process is higher than that of the dry etching process, performing the wet etching process after the dry etching process can insure the integrity of the salicide block.

In the present invention, since a portion of the dielectric layers over the photo-sensing region of the image sensor device is removed, the sensitivity of the photo-sensing region of the photodiode with respect to the light is increased.

Moreover, because the salicide block used as an anti-reflection layer is located over the photodiode, the reflection of the incident light can be avoided.

Furthermore, in the present invention, the opening exposing the salicide block is formed by performing one dry etching process and one wet etching process so that the salicide block can be prevented from being damaged by the plasma bombardment of the dry etching process.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method for forming an opening of an image sensor device, the image sensor device comprising:
a substrate;
a photodiode located over the substrate, wherein the photodiode has a photo-sensing region;
at least one transistor located on the substrate adjacent to the photodiode;
a salicide block located on the photo-sensing region of the photodiode; and
a plurality of dielectric layers located over the substrate, an interconnects being located between each of the dielectric layers without overlapping with the photo-sensing region, the dielectric layers having an opening exposing the salicide block over the photo-sensing region, wherein the method comprises:
performing a dry etching process to remove a large portion of the dielectric layers in a region used to form the opening therein; and
performing a wet etching process to removing a small portion of the dielectric layers in the region until the salicide block over the photo-sensing region is exposed.

2. The method of claim 1, before the dry etching process is performed, further comprising a step of providing a first patterned photoresist layer over the dielectric layers to expose a portion of the dielectric layers in the region.

3. The method of claim 2, after the dry etching process is performed and before the wet etching process is performed, further comprising:
removing the first patterned photoresist layer;
forming a second patterned photoresist layer over the dielectric layers to expose a portion of the dielectric layers in the region; and
performing a descum process.

4. The method of claim 3, after the wet etching process is performed, further comprising a step of removing the second patterned photoresist layer.

5. The method of claim 2, after the dry etching process is performed and before the wet etching process is performed, further comprising a step of removing polymer residue of the dry etching process by using RCA solution.

6. The method of claim 5, after the wet etching process is performed, further comprising a step of removing the first patterned photoresist layer.
